(19) United States
(12) Patent Application Publication
(10) Pub. No.: US 2018/0144995 A1
(43) Pub. Date: May 24, 2018

(54) OPTICAL INSPECTION APPARATUS AND METHOD AND METHOD OF FABRICATING SEMICONDUCTOR DEVICE USING THE APPARATUS

(71) Applicant: Samsung Electronics Co., Ltd., Suwon-si (KR)

(72) Inventors: Young-Duk Kim, Seongnam-si (KR); Byeong-Hwan Jeon, Yongin-si (KR); Kyung-Sik Kang, Bucheon-si (KR); Kang-Woong Ko, Seoul (KR); Soo-Ryong Kim, Suwon-si (KR); Tae-Joong Kim, Hwaseong-si (KR); Jun-Bum Park, Goyang-si (KR); Gil-Woo Song, Hwaseong-si (KR); Sung-Ho Jang, Hwaseong-si (KR); Hyoung-Jo Jeon, Suwon-si (KR); Jae-Chol Joo, Suwon-si (KR)

(21) Appl. No.: 15/702,870

(22) Filed: Sep. 13, 2017

(30) Foreign Application Priority Data
Nov. 23, 2016 (KR) 10-2016-0156594

(51) Int. Cl. H01L 21/66; H01L 21/78; G01B 11/06; G01B 11/02; G01N 21/88; G01N 21/95

(52) U.S. Cl. CPC H01L 22/12; H01L 21/78; G01B 11/06; G01N 2021/8848; G01N 21/8806; G01N 21/9501; G01B 11/022

(57) ABSTRACT

An optical inspection apparatus includes a broadband light source, a monochromator, an image obtaining apparatus, and an analysis device. The monochromator is configured to convert light from the broadband light source into a plurality of monochromatic beams of different wavelengths and sequentially output the monochromatic beams, where each beam has a preset wavelength width and corresponds to one of a plurality of different wavelength regions. The image obtaining apparatus is configured to allow each monochromatic beam output from the monochromator to be incident to a top surface of an inspection target without using a beam splitter, allow light reflected by the inspection target to travel in a form of light of an infinite light source, and generate 2D images of the inspection target. The analysis device is configured to analyze the 2D images of the inspection target in the plurality of wavelength regions.

### CROSS-REFERENCE TO RELATED APPLICATION

This application claims the benefit of and priority to Korean Patent Application No. 10-2016-0156594, filed on Nov. 23, 2016, in the Korean Intellectual Property Office, the disclosure of which is incorporated by reference in its entirety herein.

### BACKGROUND

### 1. Technical Field

The inventive concept relates to an optical inspection apparatus and method, and more particularly, to an optical inspection apparatus and method using spectral reflectometry (SR).

### 2. Discussion of Related Art

An SR technique is a technique of measuring a thickness and/or critical dimension (CD) of a thin film by using a phenomenon where wavelength characteristics of light reflected by the thin film are changed. When light is reflected by the thin film, reflectance may vary according to wavelength due to interference between light beams reflected at interfacial surfaces. The SR technique may include applying broadband light to a specimen of a thin film, quantitatively analyzing an extent to which a wavelength spectrum of reflected light varies, and measuring a thickness and CD of the thin film. However, it may be difficult to obtain thickness information of a wide region of interest (ROI). Also, even if it is possible to obtain thickness information of the ROI, it may take a long time to obtain the thickness information.

### SUMMARY

At least one embodiment of the inventive concept provides an optical inspection apparatus and a method capable of inspecting information of a thickness of the entire region of interest (ROI) with a high precision. At least one embodiment of the inventive concept provides a method of fabricating a semiconductor device by using the optical inspection apparatus, which may improve the reliability of the semiconductor device and yield of a semiconductor process.

According to an example embodiment of the inventive concept, there is provided an optical inspection apparatus including a light source configured to generate and output broadband light, a monochromator configured to convert the broadband light into a plurality of monochromatic beams of different wavelengths and sequentially output the monochromatic beams, wherein each beam has a preset wavelength width and corresponds to one of a plurality of different wavelength regions, illumination optics configured to allow each monochromatic beam output from the monochromator to be incident to a top surface of an inspection target at a predetermined angle of incidence (AOI), imaging optics configured to emit light reflected by the inspection target in the form of light of an infinite light source, and a detector configured to receive the emitted reflected light from the imaging optics and generate two-dimensional (2D) images of the inspection target from the received emitted reflected light. The optical inspection apparatus inspects the inspection target by analyzing the 2D images of the plurality of wavelength regions.

According to an example embodiment of the inventive concept, there is provided an optical inspection apparatus including a broadband light source, a monochromator configured to convert light output from the broadband light source into a plurality of monochromatic beams of different wavelengths and sequentially output the monochromatic beams, where each beam has a preset wavelength width and corresponds to one of a plurality of different wavelength regions, an image obtaining apparatus configured to allow each monochromatic bean output from the monochromator to be incident to a top surface of an inspection target without a beam splitter, allow light reflected by the inspection target to travel in the form of light of an infinite light source, and generate 2D images of the inspection target, and an analysis device configured to analyze the 2D images of the inspection target in the plurality of wavelength regions, which are obtained by the image obtaining apparatus.

According to an example embodiment of the inventive concept, there is provided an optical inspection method including generating 2D images of an inspection target in a plurality of wavelength regions by using a broadband light source, a monochromator, and an image obtaining apparatus, and analysis device inspecting the inspection target by analyzing the 2D images of the inspection target in the plurality of wavelength regions. The image obtaining apparatus allows light output from the monochromator to be incident to a top surface of the inspection target without a beam splitter, allows light reflected by the inspection target in a form of light of an infinite light source, and generates 2D images of the inspection target.

According to an example embodiment of the inventive concept, there is provided a method of fabricating a semiconductor device. The method includes generating 2D images of a wafer in a plurality of wavelength regions by using a broadband light source, a monochromator, and an image obtaining apparatus, an analysis device analyzing the 2D images of the wafer in the plurality of wavelength regions to determine whether a defect is present in the wafer, and performing a semiconductor process on the wafer when a result of the analyzing indicates no defect is present in the wafer. The image obtaining apparatus allows light output from the monochromator to be incident to a top surface of the wafer without a beam splitter, allows light reflected by the wafer in a form of light of an infinite light source, and generates the 2D images of the wafer.

According to an example embodiment of the inventive concept, there is provided an optical inspection apparatus including a monochromator configured to sequentially output a plurality of monochromatic beams of different wavelengths, each beam having a same preset wavelength width, first optics including a first mirror configured to apply each monochromatic beam to a top surface of a semiconductor wafer with an acute angle of incidence, second optics including an objective lens configured to receive light reflected from the top surface, a tube lens, and second mirror configured to reflect light from the object lens to the tube lens, and a camera configured to capture two-dimensional (2D) images based on light received from the tube lens. The optical inspection apparatus is configured to determine to whether the wafer has a defect by analyzing the 2D images.

### BRIEF DESCRIPTION OF THE DRAWINGS

Embodiments of the inventive concept will be more clearly understood from the following detailed description taken in conjunction with the accompanying drawings in which:

FIG. 1 is a schematic diagram showing the configuration of an optical inspection apparatus according to an example embodiment of the inventive concept;

FIG. 2 is a schematic diagram of two-dimensional (2D) images relative to a wavelength obtained by the optical inspection apparatus of FIG. 1;

FIGS. 3A and 3B are respectively a perspective view and a graph illustrating principles by which a thickness of a thin film is measured by using an optical inspection apparatus according to an example embodiment of the inventive concept;

FIG. 4 is a detailed diagram showing the configuration of a monochromator in an optical inspection apparatus according to an example embodiment of the inventive concept;

FIG. 5 is a detailed diagram showing the configuration of an illumination optics of an image obtaining apparatus in an optical inspection apparatus according to an example embodiment of the inventive concept;

FIGS. 6A to 6C are a cross-sectional view and graphs showing that there are no variations in wavelength and sensitivity relative to angle of incidence (AOI) in an optical inspection apparatus according to an example embodiment of the inventive concept;

FIGS. 7A and 7B are detailed diagrams showing the configurations of a collimator and a polarizer of an illumination optics of an image obtaining apparatus in an optical inspection apparatus according to an example embodiment of the inventive concept;

FIGS. 8A and 8B are diagrams illustrating the concept of a double telecentric optics to which an imaging optics of an image obtaining apparatus is applied, in an optical inspection apparatus according to an example embodiment of the inventive concept;

FIG. 9A is a plan view of a 2D image of a region of interest (ROI) of a wafer, which is obtained by an optical inspection apparatus according to an example embodiment of the inventive concept;

FIG. 9B is a graph of reflectance relative to wavelength in each pixel of the 2D image of FIG. 9A;

FIG. 9C is a perspective view of a height profile image of the ROI based on the graph of FIG. 9B;

FIG. 10 is a flowchart of an optical inspection method according to an example embodiment of the inventive concept;

FIG. 11 is a detailed flowchart of an operation of generating a 2D image of an inspection target in the optical inspection method of FIG. 10; and

FIG. 12 is a flowchart of a method of fabricating a semiconductor device by using an optical inspection method according to an example embodiment of the inventive concept.

### DETAILED DESCRIPTION OF THE EXEMPLARY EMBODIMENTS

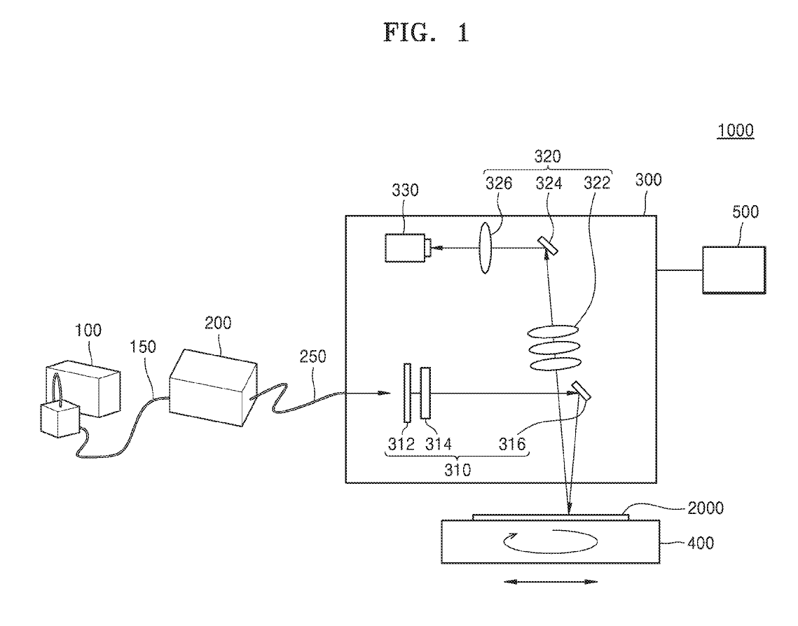

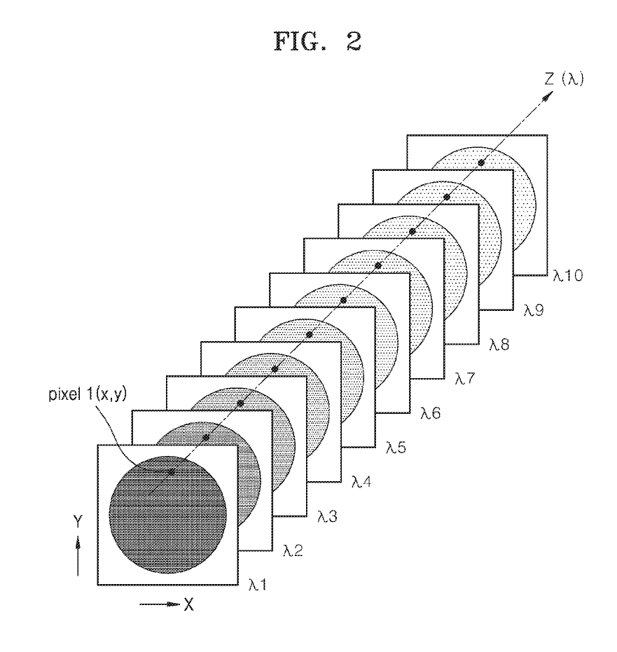

FIG. 1 is a schematic diagram showing the configuration of an optical inspection apparatus 1000 according to an example embodiment of the inventive concept, and FIG. 2 is a schematic diagram of two-dimensional (2D) images relative to a wavelength obtained by the optical inspection apparatus 1000 of FIG. 1.

Referring to FIG. 1, the optical inspection apparatus 1000 according to the present embodiment includes a light source 100, a monochromator 200, an image obtaining apparatus 300, a stage 400, and an analysis device 500.

In an example embodiment, the light source 100 is a broadband light source configured to generate and output broadband light. For example, in the optical inspection apparatus 1000 according to the present embodiment, the light source 100 may generate and output light having a band (e.g., wavelength) of about (or exactly) 170 nm to about (or exactly) 2100 nm. The light source 100 may be configured as a broadband light source and provide light of various spectra.

In an embodiment, the monochromator 200 converts broadband light output by the light source 100 into monochromatic light and outputs the monochromatic light. Here, the monochromatic light may refer to light having a very short wavelength width. For example, the monochromatic light may be light having a wavelength width of several nm. The monochromator 200 may output not only monochromatic light of one wavelength region but also monochromatic beams of a plurality of wavelength regions. For example, the monochromator 200 may output a plurality of monochromatic beams in a predetermined wavelength range. Also, while sweeping at a preset wavelength width in a predetermined wavelength range, the monochromator 200 may output a plurality of monochromatic beams.

For example, in the optical inspection apparatus 1000 according to the present embodiment, the monochromator 200 receives broadband light from the light source 100 and outputs monochromatic light having a wavelength width of about (or exactly) 5 nm. While sweeping at wavelength intervals of about (or exactly) 5 nm in a wavelength range of about (or exactly) 250 nm (e.g., lower limit of wavelength range) to about (or exactly) 800 nm (e.g., upper limit of wavelength range), the monochromator 200 may output monochromatic beams. Specifically, when outputting the monochromatic beams, the monochromator 200 may firstly output a first monochromatic beam having a wavelength of about (or exactly) 250 nm to about (or exactly) 255 nm, secondly output a second monochromatic beam having a wavelength of about (e.g., or exactly) 255 nm to about (or exactly) 260 nm, and thirdly output a third monochromatic beam having a wavelength of about (or exactly) 260 nm to about (or exactly) 265 nm.

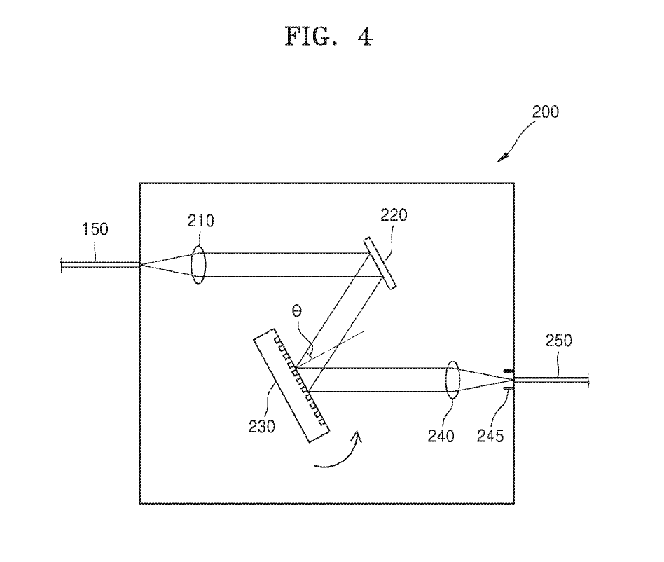

While sweeping at a preset wavelength width, the monochromator 200 may sweep not continuously but intermittently. For example, while sweeping intermittently during a first period, the monochromator 200 may output a plurality of monochromatic beams by firstly outputting a first monochromatic beam having a wavelength of about (or exactly) 250 nm to about (or exactly) 255 nm, secondly outputting a second monochromatic beam having a wavelength of about (or exactly) 260 nm to about (or exactly) 265 nm, and thirdly outputting a third monochromatic beam having a wavelength of about (or exactly) 270 nm to about (or exactly) 275 nm. For example, while sweeping intermittently during a second period after the first period, the monochromator 200 may output a plurality of monochromatic beams by fourthly outputting a fourth monochromatic beam having a wavelength of about (or exactly) 255 nm to about (or exactly) 260 nm, fifthly outputting a fifth monochromatic beam having a wavelength of about (or exactly) 265 nm to about (or exactly) 270 nm, and sixthly outputting a sixth monochromatic beam having a wavelength of about (or exactly) 275 nm to about (or exactly) 280 nm. While the above examples discuss sweeping from the lower limit of the wavelength range to a value less than the upper limit of the wavelength range, in alternate embodiments, the sweeping may continue until reaching the upper limit. Further, the sweeping may begin from a value between the lower and upper limits and continue until reaching the upper limit. The wavelength interval or width may be modified in alternate embodiments. For example, in an alternate embodiment, the wavelength width could be 1 nm, 2 nm, 3 nm, or 4 nm. An internal structure and sweeping principles of the monochromator 200 will be described in more detail with reference to FIG. 4.

In an embodiment, broadband light from the light source 100 is transmitted to the monochromator 200 through a first optical fiber 150. In an embodiment, light from the monochromator 200 is transmitted to the image obtaining apparatus 300 through a second optical fiber 250. The first optical fiber 150 and the second optical fiber 250 may be commercially usable optical fibers. In an embodiment, light output from the light source 100 to the first optical fiber 150 has a coupling numerical aperture (NA) of about (or exactly) 0.22. In an embodiment, light output from the monochromator 200 to the second optical fiber 250 has a coupling NA of about (or exactly) 0.22. However, the coupling NA of light output to first optical fiber 150 and the second optical fiber 250 is not limited to these numerical values.

The image obtaining apparatus 300 includes illumination optics 310, imaging optics 320, and a charge-coupled device (CCD) camera 330.

In an embodiment, the illumination optics 310 irradiates or illuminates a region of interest (ROI) of an inspection target 2000 located on the stage 400 with light output by the monochromator 200. The illumination optics 310 includes a collimator 312, a polarizer 314, and a first mirror 316.

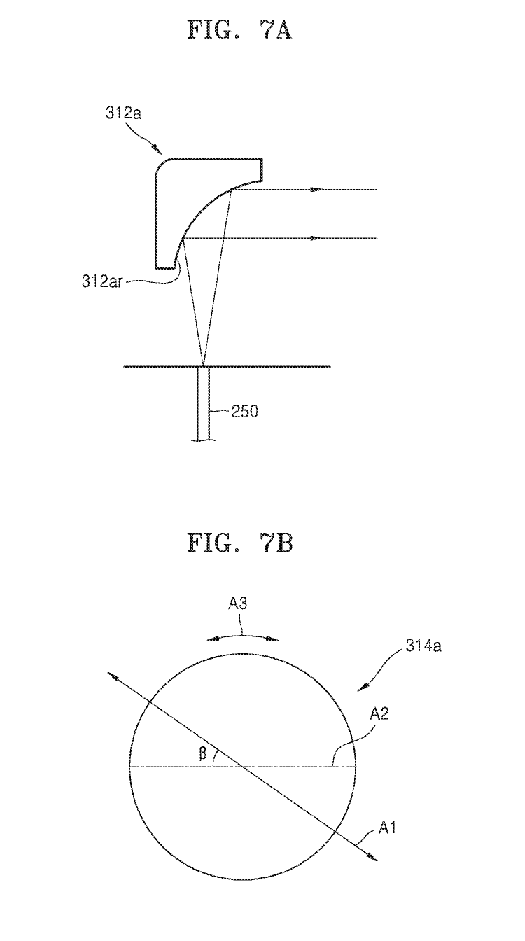

The collimator 312 collimates light output from the monochromator 200 to generate collimated light and outputs the collimated light. In an embodiment, the polarizer 314 linearly polarizes the collimated light from the collimator 312. For example, the polarizer 314 may transmit only a p polarizing element (or a horizontal element) or an s polarizing element (or a vertical element) from among incident light and output the p polarizing element or the s polarizing element to linearly polarize the incident light. An iris may be located between the collimator 312 and the polarizer 314 to control an optical size. In an embodiment, an end of the second optical fiber 250 outputting a monochromatic beam is aligned with a center of the collimator 312. In an embodiment the collimator 312 and the polarizer 314 have a same or similar orientation. The collimator 312 and the polarizer 314 will be described in further detail with reference to FIGS. 7A and 7B.

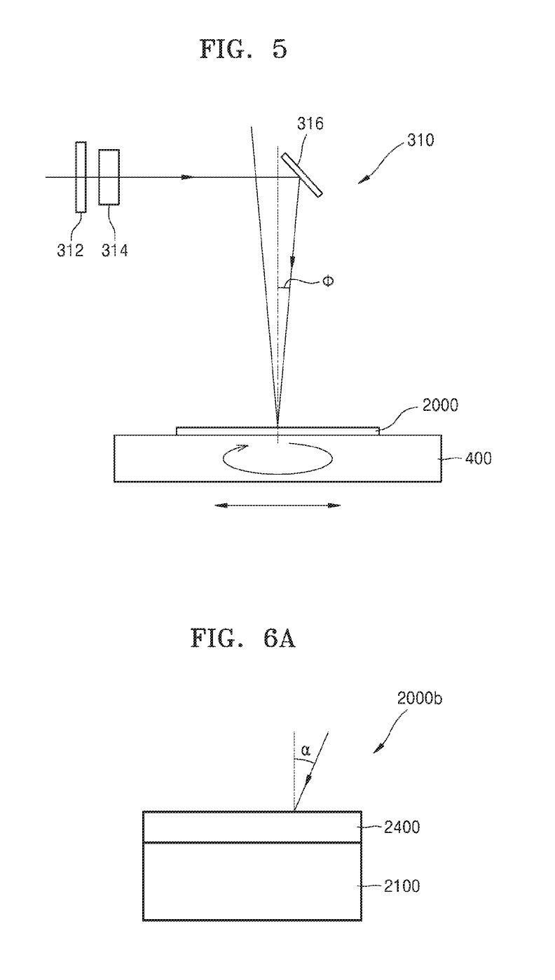

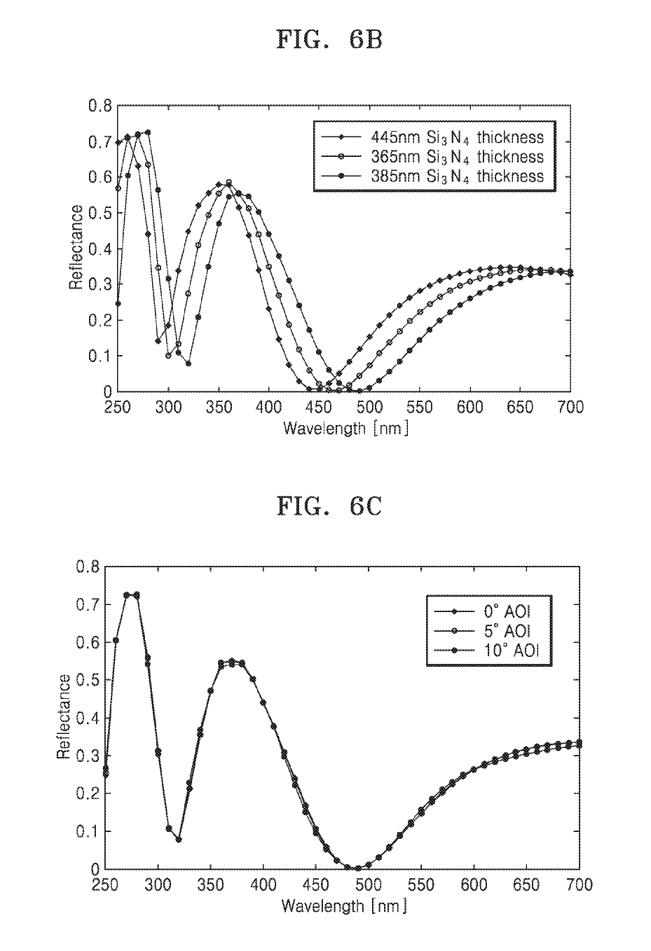

The first mirror 316 reflects the linearly polarized light output by the polarizer 314 and applies the reflected light onto the ROI of the inspection target 2000 located on the stage 400. The first mirror 316 may be referred to as a folding mirror. The first mirror 316 may change a path of light due to a reflection process and allow the light to be incident to a top surface of the inspection target 2000 at a predetermined angle of incidence (AOI). Due to the first mirror 316, the light may be incident to the top surface of the inspection target 2000 at the predetermined AOI so that the illumination optics 310 is configured as inclined optics with respect to the inspection target 2000. The inclined optics will be described in further detail with reference to FIGS. 5, 6A, and 6B.

The imaging optics 320 allows light reflected by the inspection target 2000 to be incident to the CCD camera 330 and form an image of the inspection target 2000 on the CCD camera 330. In an embodiment, only a portion of the inspection target 2000 corresponding to a field of view (FOV) is imaged on the CCD camera 330 by the imaging optics 320. The FOV may be determined by the imaging optics 320 and include an ROI. The imaging optics 320 includes an objective lens 322, a second mirror 324, and a tube lens 326.

The objective lens 322 may include at least one lens. In an embodiment, the objective lens 322 condenses light to allow the condensed light to be incident to the inspection target 2000. In an embodiment, the objective lens 322 collimates light from the inspection target 2000 and allows the collimated light to be incident to the second mirror 324. In an embodiment, the objective lens 322 has an orientation that enables the light reflected off the top surface to pass through a center of the objective lens 322.

The second mirror 324 reflects light from the objective lens 322 to be incident to the tube lens 326. The second mirror 324 changes a path of light output through the objective lens 322 due to a reflection process and allows a distance between the inspection target 2000 and the CCD camera 330 to be reduced. Thus, the second mirror 324 may contribute toward reducing a size of the image obtaining apparatus 300. For example, when the second mirror 324 is not included in the imaging optics 320, light from the objective lens 322 travels in one direction, and the CCD camera 330 accordingly needs to be also located in the same direction as the direction in which the light from the objective lens 322 travels. Accordingly, a reduction in the size of the image obtaining apparatus 300 may be limited by a distance required by the imaging optics 320. However, in the optical inspection apparatus 1000 according to the present embodiment, since the imaging optics 320 includes the second mirror 324 to change a path of light, the size of the image obtaining apparatus 300 may be reduced, and a size of the entire optical inspection apparatus 1000 may also be reduced.

Although only one second mirror 324 is illustrated in the optical inspection apparatus 1000 of FIG. 1, the number of second mirrors 324 is not limited thereto. For example, the optical inspection apparatus 1000 may include at least two second mirrors 324 in alternate embodiments. In an exemplary embodiment, the second mirror 324 is omitted. When the second mirrors 324 are provided in a different number than one or omitted, a path of light may be changed so that a position of the CCD camera 330 is changed.

In an embodiment, the tube lens 326 forms a middle image from light reflected by the second mirror 324 and allows the reflected light to be incident to an imaging lens (not shown) of the CCD camera 330. The tube lens 326 may be located between the objective lens 322 and the imaging lens and form the middle image to support the objective lens 322. The imaging lens may be included in the CCD camera 330 and include at least one lens. The imaging lens may form an image of an object on an image sensor included in the CCD camera 330. Also, the imaging lens may function as a magnifying lens. If the imaging lens functions as the magnifying lens, a magnification of the imaging optics 320 may be indicated by a product of a magnification of the object lens 322 and a magnification of the imaging lens.

In general, as a magnification of an imaging optics increases, the intensity of received light decreases and an image darkens. However, in the optical inspection apparatus 1000 according to the present embodiment, the illumination optics 310 may be configured as inclined optics to ensure a sufficient light intensity. Thus, the imaging optics 320 may be configured to have a magnification ratio of several times to several tens of times. More specifically, the imaging optics 320 may have a magnification ratio of two to ten times. For example, in the optical inspection apparatus 1000 according to the present embodiment, the imaging optics 320 may have a magnification ratio of 4 times.

In addition, lenses included in the imaging optics 320 to increase light intensity may have a low reflectance over a wide wavelength band. For example, the lenses included in the imaging optics 320 may be specially coated with MgF₂ so that each of the lenses have a reflectance of less than about (or exactly) 3% in a wavelength band of about (or exactly) 250 nm to about (or exactly) 800 nm. In an example embodiment, the imaging optics 320 has an NA of about (or exactly) 0.03 to about (or exactly) 0.08 to increase the resolution and compatibility of spectral reflectometry (SR) signals. For example, in the optical inspection apparatus 1000 according to the present embodiment, the imaging optics 320 may have an NA of about (or exactly) 0.05.

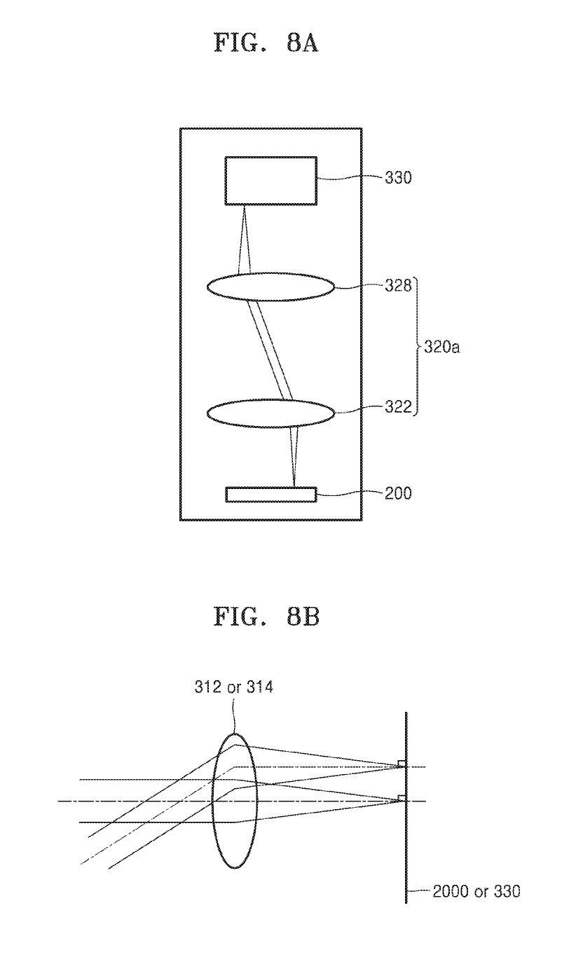

In the optical inspection apparatus 1000 according to the present embodiment, the imaging optics 320 may include a double telecentric optics. In an embodiment, a telecentric optics refers to optics configured to allow light to travel in the form of light of an infinite light source. A double telecentric optics may refer to an optics including telecentric optics provided at both a side of the inspection target 2000 and a side of the CCD camera 330. The telecentric optics may include a compound lens that has its entrance or exit pupil at infinity. An entrance pupil at infinity makes the lens object-space telecentric. An exit pupil at infinity makes the lens image-space telecentric. If both pupils are at infinity, the lens is double telecentric or bi-telecentric. The double telecentric optics will be described in further detail with reference to FIGS. 8A and 8B.

The CCD camera 330 may receive light reflected by the inspection target 2000 through the imaging optics 320 so that an image of the inspection target 2000 is formed on the image sensor, and generates a two dimensional (2D) image of the inspection target 2000. Also, the CCD camera 330 may generate 2D images of the inspection target 2000 in a plurality of wavelength regions. Here, the 2D image of the inspection target 2000 is not a 2D image of the entire inspection target 2000, but a 2D image of an ROI of the inspection target 2000. Unless described otherwise below, the inspection target 2000 may be substantially synonymous with the ROI of the inspection target 2000.

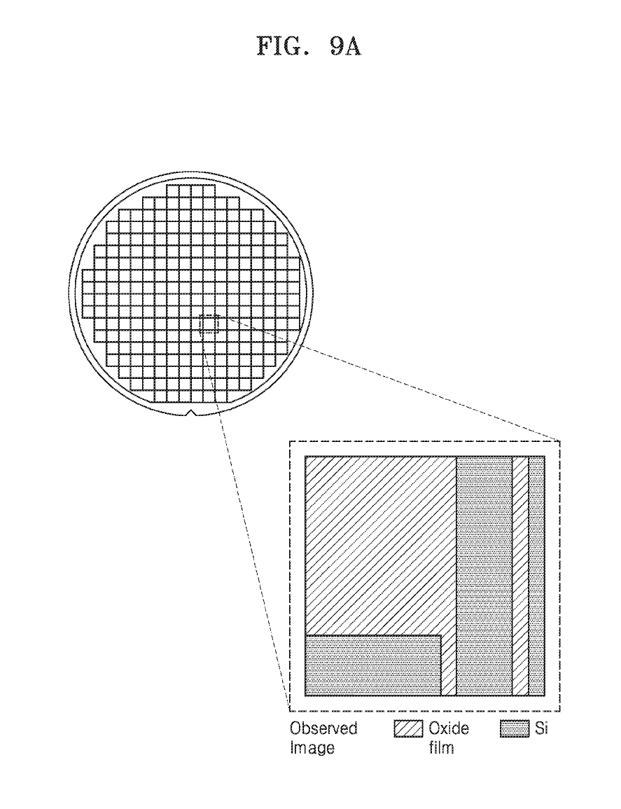

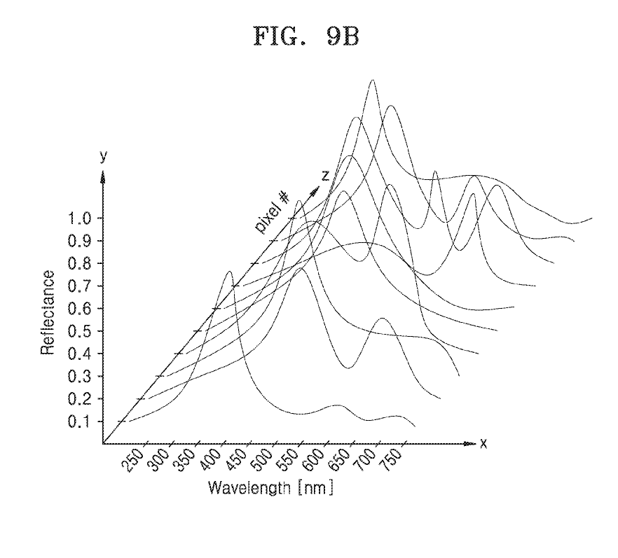

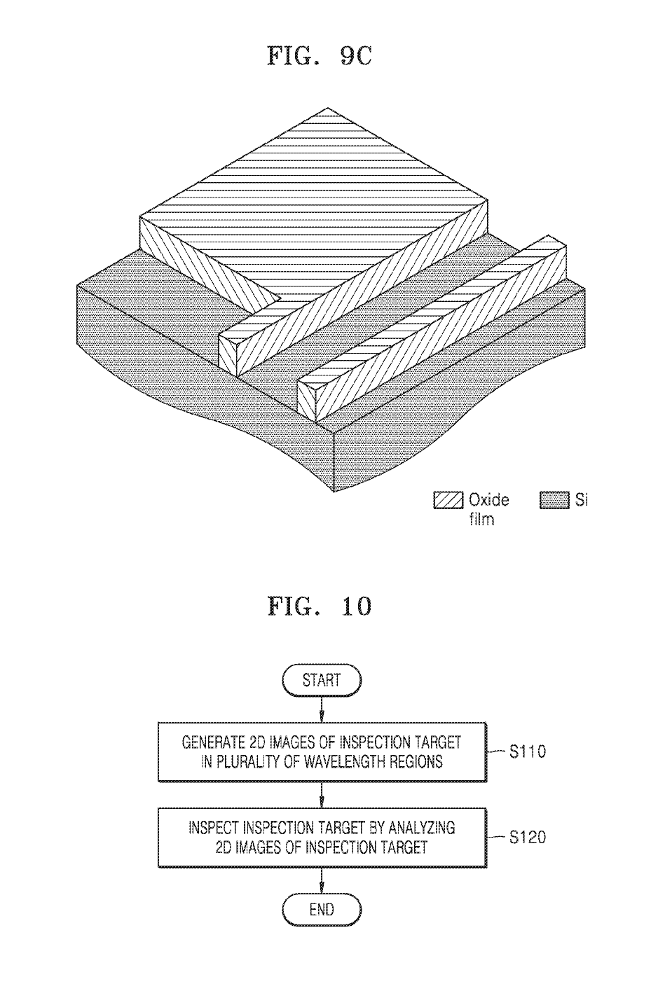

FIG. 2 shows 2D images of the inspection target 2000 in a plurality of wavelength regions λ1, λ2, . . . , and λ10. For example, the first 2D image among the plurality illustrated in FIG. 2 is generated when a first monochromatic beam for a first wavelength region λ1 is applied by the monochromator 200. Here, each of the x-axis and the y-axis may indicate a position on an x-y plane corresponding to the top surface of the inspection target 2000, and the z-axis may indicate a plurality of wavelength regions. Also, a pixel 1(x,y) may correspond to one pixel of an ROI of the inspection target 2000. Thus, a graph of an intensity or reflectance relative to wavelength region in each of pixels may be obtained by extracting an intensity or reflectance of each wavelength region in each of the pixels. The reflectance graph will be described in further detail with reference to FIG. 9B.

Although FIG. 2 illustrates only ten wavelength regions, the number of wavelength regions is not limited to ten. For example, the number of wavelength regions may be nine or fewer or eleven or more. In FIG. 2, a 2D image of the inspection target 2000 is illustrated as a circular type for brevity. However, the 2D image of the inspection target 2000 may have one of various shapes according to a shape of an ROI to be inspected.

In the optical inspection apparatus 1000 according to the present embodiment, although the image obtaining apparatus 300 is illustrated as including the CCD camera 330 as a detector configured to generate 2D images, the detector is not limited to the CCD camera 330. For example, the image obtaining apparatus 300 may instead include a complementary-metal-oxide semiconductor (CMOS) camera as a detector.

In the optical inspection apparatus 1000 according to the present embodiment, the CCD camera 330 may have high quantum efficiency (QE) to compensate for lack of light intensity in an ultraviolet (UV) band. For instance, the CCD camera 330 may have a high QE of about (or exactly) 30% or higher in the UV band. Also, since broadband light of the light source 100 has a different light intensity according to wavelength, the optical inspection apparatus 1000 according to the present embodiment may adopt a dynamic shutter speed technique of dynamically controlling a shutter speed according to intensity of incident light. Thus, the CCD camera 330 may remove non-uniformity in light intensity between a wavelength region having extra light intensity and a wavelength region having insufficient light intensity and minimize occurrence of errors.

The stage 400 is a device on which the inspection target 2000 is located. In an embodiment, the stage 400 moves the inspection target 2000 due to linear and rotative movement. For example, the stage 400 may move in a linear direction and/or rotate to one of various angles. Thus, the stage 400 may be referred to as an R-θ stage. In FIG. 1, a bi-directional linear arrow below the stage 400 refers to linear movement of the stage 400, and an elliptical arrow in the stage 400 refers to rotative movement of the stage 400. The stage 400 is not limited to the R-θ stage and may be an x-y-z stage. When the stage 400 is an x-y-z stage, the stage 400 is capable of linearly moving in x, y, and z directions and moving the inspection target 2000. The stage 400 may include a motor and/or an actuator to enable its movement.

The inspection target 2000 may be one of various devices serving as inspection targets, such as a wafer, a semiconductor package, a semiconductor chip, and a display panel. For example, in the optical inspection apparatus 1000 according to the present embodiment, the inspection target 2000 may be a semiconductor wafer. Here, the wafer may be a wafer including a thin film formed on a substrate. Periodic patterns, such as line-and-space (L/S) patterns, or non-periodic patterns may be formed on the thin film. The thin film may also include regions without any patterns.

In an embodiment, the analysis device 500 is connected to the image obtaining apparatus 300 (i.e., the CCD camera 330), receives information about the 2D image of the inspection target 2000 from the CCD camera 330, and analyzes the information. The analysis device 500 may be, for example, a personal computer (PC), a workstation, or a supercomputer, which may include an analysis process. In some cases, the analysis device 500 may be unified with the CCD camera 330 and included in a portion of a detector or a detection apparatus.

In an embodiment, the analysis device 500 generates a reflectance graph for inspection based on 2D images of the inspection target 2000 in a plurality of wavelength regions. Also, the analysis device 500 may compare the reflectance graph for inspection with a reference reflectance graph stored in a database and determine a thickness and a pattern critical dimension (CD) of a thin film in an ROI of the inspection target 2000.

After compensating for a difference in intensity and a QE difference of the CCD camera 330 between different wavelength regions of broadband light, the analysis device 500 generates a reflectance graph for inspection based on the 2D image and compares the reflectance graph for inspection with a reference reflectance graph. Intensity information of the 2D image of the inspection target 2000, which is obtained by using the CCD camera 330, may not precisely represent reflectance of the inspection target 2000. Thus, after correcting or compensating for a transmittance of the entire optics by using a standard specimen of which reflectance is known, the analysis device 500 generates a reflectance graph for inspection and compares the reflectance graph for inspection with a reference reflectance graph. Accordingly, the analysis device 500 may determine a thickness of a thin film and a pattern CD of the thin film in an ROI of the inspection target 2000 once with a high precision of measurements.

In an embodiment, the optical inspection apparatus 1000 according to the present embodiment converts broadband light into monochromatic light having a preset wavelength width by using the monochromator 200 and outputs the monochromatic light. In this case, while sweeping at intervals of the wavelength width, the monochromator 200 outputs a plurality of monochromatic beams in a plurality of wavelength regions.

In the optical inspection apparatus 1000 according to the present embodiment, the illumination optics 310 of the image obtaining apparatus 300 may be configured as an inclined optics with respect to the inspection target 2000 to ensure a sufficient light intensity and improve light use efficiency. For example, by configuring the illumination optics 310 as the inclined optics, the illumination optics 310 may ensure a much higher light intensity than a typical illumination optics using a beam splitter (BS). Also, the imaging optics 320 of the image obtaining apparatus 300 may be configured as a double telecentric optics. Thus, chromatic aberration, which may occur when a wide wavelength band is used in an SR technique using a 2D image, may be minimized to improve precision of measurements. For example, by configuring the imaging optics 320 as a double telecentric optics, a difference in magnification between FOVs of the inclined optics and chromatic aberration may be removed to greatly improve precision of measurement.

Furthermore, in the optical inspection apparatus 1000 according to the present embodiment, the imaging optics 320 may adopt a relatively high NA of about (or exactly) 0.03 to about (or exactly) 0.08 and a magnification ratio of 2 times to 10 times, based on the illumination optics 310 that is configured as the inclined optics, so as to increase resolution and ensure a sufficient image brightness. Also, the CCD camera 330 of the image obtaining apparatus 300 may have high QE in a UV band and compensate for lack of light intensity in the UV band. Also, the CCD camera 330 of the image obtaining apparatus 300 may adopt a dynamic shutter speed technique and minimize non-uniformity in light intensity between wavelength regions. Accordingly, occurrence of errors due to lack of light intensity or non-uniformity in light intensity between the wavelength regions may be minimized.

In addition, a structure or principles of the optical inspection apparatus 1000 according to the present embodiment may be applied to typical optical inspection apparatuses. For example, when the optical inspection apparatus 1000 is applied to a typical optical inspection apparatus to inspect an inspection target, optics of the typical optical inspection apparatus may be revised into an inclined optics and a double telecentric optics. Transmittance characteristics of the optics may be measured, and the analysis device 500 may appropriately revise an analysis process. Thus, a thickness or a CD of a thin film of the inspection target 2000 may be measured by using the revised optical inspection apparatus. When the revised optical inspection apparatus is used, since a different CCD camera is used, an operation of correcting QE may be performed according to the type of the CCD camera.

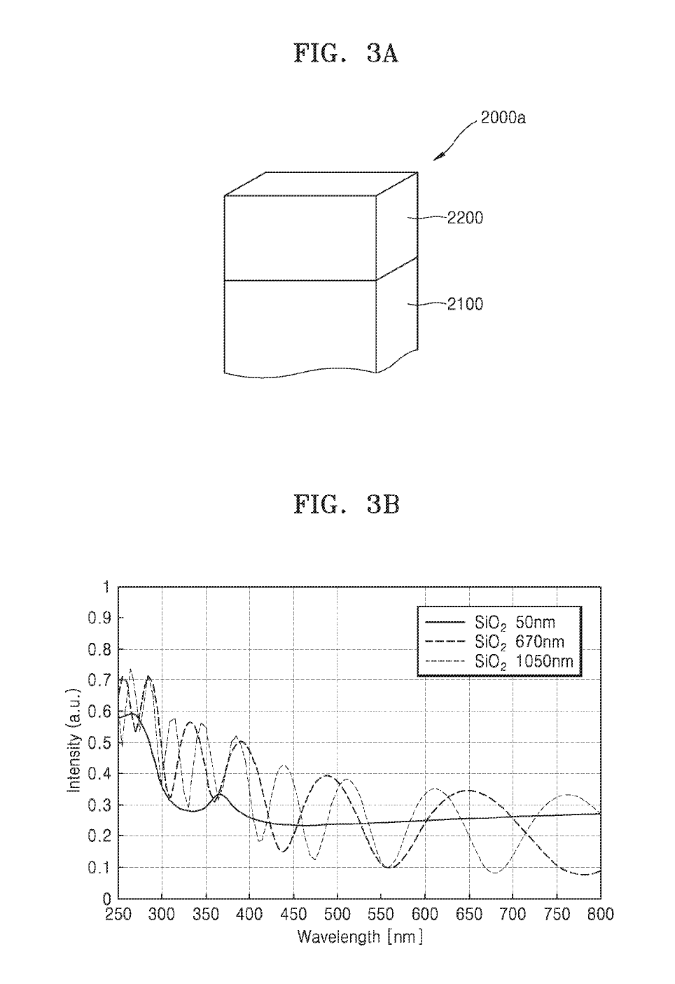

FIGS. 3A and 3B are respectively a perspective view and a graph illustrating principles by which a thickness of a thin film is measured by using an optical inspection apparatus according to an embodiment.

Referring to FIG. 3A, an inspection target 2000a may include a silicon oxide (SiO₂) layer 2200 formed on a substrate 2100. Here, the substrate 2100 may be a silicon substrate, and the silicon oxide layer 2200 may have a thickness of about (or exactly) 50 nm, about (or exactly) 670 nm, or about (or exactly) 1050 nm.

FIG. 3B is a graph of intensity relative to wavelength, which is obtained by irradiating the inspection target 2000a of FIG. 3A in each wavelength region and detecting reflected light. Also, FIG. 3B is a graph of intensity relative to wavelength, which is obtained according to a thickness of the silicon oxide layer 2200. As shown in FIG. 3B, it can be confirmed that an intensity graph varies according to the thickness of the silicon oxide layer 2200. For example, the intensity of the 2D image received by the camera 330 when the monochromator 200 applies a monochromatic beam having a wavelength of about 250 nm along with the wavelength could be plotted in the graph as a first point, the intensity of the 2D image received by the camera 330 when the monochromator 200 applies a monochromatic beam having a wavelength of about 300 nm along with the wavelength could be plotted in the graph as a second point, etc.

From the above-described results, the thickness of the thin film may be measured by using the following method. To begin with, in a thin film structure including specific material layers, various curves for intensity relative to wavelength are obtained by varying a structure and thickness of a thin film, and stored in a database as reference intensity curves. Thereafter, in an inspection target 2000 including the same material layer as the thin film structure, an inspection curve of intensity relative to wavelength may be obtained by using the optical inspection apparatus 1000. The inspection curve of intensity relative to wavelength may be compared with reference intensity curves. Thus, information of a structure or thickness of a thin film of the inspection target 2000 may be obtained. Also, when it is intended to determine whether the thin film has an appropriate structure or thickness in the inspection target 2000, an inspection curve of intensity relative to wavelength in the inspection target 2000 may be obtained by using the optical inspection apparatus 1000. Thereafter, an inspection curve of intensity relative to wavelength may be compared with the reference intensity curves corresponding to the structure or thickness of the thin film, and it may be determined whether the inspection curve of intensity relative to wavelength is similar to the reference intensity curves within a permitted limit. It may be determined whether the thin film has an appropriate structure or thickness in the inspection target 2000 based on the determination result.

The optical inspection apparatus 1000 according to the present embodiment may obtain a 2D image of the inspection target 2000 according to each wavelength, detect an intensity of each of pixels of the 2D image according to each wavelength, and obtain information regarding a structure or thickness of a thin film in the entire region of the ROI of the inspection target 2000 (i.e., a wafer). The intensity of a 2D image may be an average of the intensity of all the pixels of the 2D image. For reference, FIG. 3A is a perspective view corresponding to one pixel of the 2D image of the inspection target 2000, and FIG. 3B is a graph of intensity relative to wavelength in the pixel shown in FIG. 3A. In 3B, a y-axis is indicated by intensity (arbitrary unit). Further, even if the y-axis is indicated by reflectance instead of intensity, there is no substantial difference.

FIG. 4 is a detailed diagram showing the monochromator 200 in an optical inspection apparatus 1000 according to an example embodiment of the inventive concept.

Referring to FIG. 4, in the optical inspection apparatus 1000 according to the present embodiment, the monochromator 200 includes a collimator 210, a mirror 220, a grating device 230, a condensing lens 240, and a slit 245. As described above, the monochromator 200 may convert broadband light output from the light source (refer to 100 in FIG. 1) into monochromatic light and output the monochromatic light.

The collimator 210 may collimate light that is incident through a first optical fiber 150. The mirror 220 may change a path of light due to a reflection process and allow the light to be incident to the grating device 230 at a predetermined AOI θ.

In an embodiment, the grating device 230 is configured to extract monochromatic light and split incident light according to wavelength and reflect the split light. A wavelength of light reflected by the grating device 230 to a specific position may depend on an angle (i.e., AOI θ) of light incident to the grating device 230 due to optical properties that an angle at which primary light is reflected due to diffraction varies according to wavelength of light. Accordingly, as illustrated with an arrow, the AOI θ of light may be changed by rotating the grating device 230 so that the wavelength of monochromatic light reflected to a specific position is changed.

The condensing lens 240 may be located in a specific position with respect to the grating device 230. Monochromatic light to be extracted, from among light split by the grating device 230 according to wavelength, may be incident to the condensing lens 240. The incident monochromatic light may be condensed by the condensing lens 240 and incident to the second optical fiber 250 through the slit 245. As described above, by rotating the grating device 230, split light having a different wavelength may be incident to the condensing lens 240. Accordingly, by rotating the grating device 230, monochromatic light having a different wavelength may be condensed and output by the condensing lens 240. In an embodiment, a concave mirror is used instead of the condensing lens 240. When the concave mirror is used, a path of light may be changed so that positions of the slit 245 and the second optical fiber 250 may need to be changed.

Incident light may be split according to wavelength by using a prism instead of the grating device 230. When the prism is used, a position of the condensing lens 240 may be changed without changing an AOI in order to vary a wavelength of monochromatic light emitted through the condensing lens 240. In an embodiment, the monochromator 200 further includes an incidence slit located at a portion of a front end of the collimator 210, which is combined with the first optical fiber 150. In an embodiment, the grating device 230 is a diffraction grating, which is an optical component with a periodic structure, which splits and diffracts light into several beams travelling in different directions.

FIG. 5 is a detailed diagram showing illumination optics 310 of an image obtaining apparatus in an optical inspection apparatus 1000 according to an example embodiment of the inventive concept.

Referring to FIG. 5, in the optical inspection apparatus 1000 according to the present embodiment, the illumination optics 310 is configured as inclined optics with respect to an inspection target 2000. An inclined optics may refer to optics configured to allow light to be incident to the inspection target 2000 at not a vertical angle but an inclined angle with respect to a top surface of the inspection target 2000. That is, light may be incident through the illumination optics 310 to the top surface of the inspection target 2000 at a predetermined AOI φ. In an embodiment, the AOI φ is an acute angle. The AOI φ may be, for example, about (or exactly) 3° to about (or exactly) 10°. In the optical inspection apparatus 1000 according to the present embodiment, the illumination optics 310 may allow light to be incident to the inspection target 2000 at an AOI φ of about (or exactly) 5°. The concept of the inclined optics may be applied not only to the illumination optics 310 but also to the imaging optics 320. For example, since an AOI φ is equal to a reflection angle according to the law of reflection of light, when the illumination optics 310 is configured as inclined optics, the imaging optics 320 may also be configured as inclined optics.

As described with reference to FIG. 5, the illumination optics 310 includes a collimator 312, a polarizer 314, and a first mirror 316. By changing a path of light by using the first mirror 316, the illumination optics 310 is configured as inclined optics. When the illumination optics 310 is configured as the inclined optics, use efficiency of light may sharply increase. Thus, a magnification of several to several tens of times may be applied to the imaging optics (refer to 320 in FIG. 1) so that an enlarged image that maintains a sufficient brightness is formed on the CCD camera 330. As a result, precision of measurements and analysis precision may be improved.

For reference, in a typical SR apparatus, the illumination optics and the imaging optics may each be configured as a vertical optics with respect to the inspection target 2000 by using a beam splitter BS. In the SR apparatus using the beam splitter BS, when light is incident to the inspection target 2000 through the beam splitter BS, optical loss of about (or exactly) ½ may occur due to properties of the beam splitter BS. Also, when light reflected by the inspection target 2000 travels to the CCD camera 330 through the beam splitter BS, optical loss of about (or exactly) ½ may occur again. Thus, a total of optical loss of about (or exactly) ¾ may occur. By comparison, in the optical inspection apparatus 1000 according to the present embodiment, since each of the illumination optics 310 and the imaging optics 320 is configured as inclined optics, there may be no optical loss. Accordingly, if optical loss due to other optical devices is ignored, the optical inspection apparatus 1000 according to the present embodiment may use almost 100% of light incident from the monochromator 200 to the image obtaining apparatus 300.

FIG. 6A is a cross-sectional view and FIGS. 6B to 6C are graphs showing that there are no variations in wavelength and sensitivity relative to AOI in an optical inspection apparatus 1000 according to an example embodiment of the inventive concept.

Referring to FIG. 6A, an inspection target 2000b may include a silicon nitride (Si₃N₄) layer 2400 formed on a substrate 2100. Here, the substrate 2100 may be a silicon substrate, and the silicon nitride layer 2400 may have a thickness of about (or exactly) 385 nm, about (or exactly) 365 nm, or about (or exactly) 445 nm. Light is incident through an illumination optics (refer to 310 in FIG. 1 or FIG. 5) to a top surface of the silicon nitride layer 2400 at a predetermined AOI α.

FIG. 6B is a graph of reflectance relative to wavelength, which is obtained by vertically applying light in each wavelength region to a top surface of the inspection target 2000b of FIG. 6A and detecting reflected light. Also, FIG. 6B is a graph of reflectance relative to wavelength in respective thicknesses of the silicon nitride layer 2400. From FIG. 6B, it can be confirmed that a reflectance curve differs according to a thickness of the silicon nitride layer 2400. For example, when the silicon nitride layer 2400 has a thickness of about (or exactly) 445 nm, about (or exactly) 365 nm, and 385 nm, respectively, it can be seen that reflectance curves have second peaks at wavelengths of about (or exactly) 340 nm, about (or exactly) 350 nm, and about (or exactly) 370 nm, respectively. Accordingly, as described above with reference to FIGS. 3A to 3C, a thickness of the silicon nitride layer 2400 may be measured based on a difference between curves of reflectance relative to wavelength, which is obtained according to a thickness of a thin film.

FIG. 6C is a graph of reflectance relative to wavelength, which is obtained by applying light in each wavelength region at AOIs α of about (or exactly) 0°, about (or exactly) 5°, and about (or exactly) 10° to the top surface of the inspection target 2000b of FIG. 6A and detecting reflected light. In this case, the silicon nitride layer 2400 may have a thickness of about (or exactly) 385 nm. From FIG. 6C, it can be confirmed that there are little differences between curves of reflectance relative to wavelength, which are obtained according to the AOI α.

Therefore, even if the illumination optics 310 is configured as the inclined optics, the optical inspection apparatus 1000 may effectively determine a state (i.e., a thickness or CD) of a thin film.

For reference, when light reflected by the inspection target 2000 is expressed by a graph of intensity (arbitrary unit), shapes of curves of a vertical optics and inclined optics may depend on a basis. For example, when light firstly incident to the image obtaining apparatus 300 is provided as a basis, the vertical optics may have a generally very low intensity, while the inclined optics may have a generally high intensity, depending on whether or not a beam splitter is used. Meanwhile, when light reflected by the inspection target 2000 is expressed by a graph of reflectance, a curve of a vertical optics may have substantially the same shape as a curve of an inclined optics as can be seen from FIG. 6C. In this case, since reflectance is a ratio of light reflected by the inspection target 2000 to light incident to the inspection target 2000, the reflectance may be irrelevant to a beam splitter.

FIGS. 7A and 7B are detailed diagrams showing the configurations of a collimator 312a and a polarizer 314a of an illumination optics 310 of an image obtaining apparatus in an optical inspection apparatus 1000 according to an example embodiment of the inventive concept.

Referring to FIG. 7A, in the optical inspection apparatus 1000 according to the present embodiment, the collimator 312a of the illumination optics 310 may include a reflectance-type aspherical mirror. In an embodiment, a reflection surface 312ar of the collimator 312a is coated with a material capable of maximizing reflectance of light in a UV band. As shown in FIG. 7A, the collimator 312a may reflect and collimate light from a second optical fiber 250. In the optical inspection apparatus 1000 according to the present embodiment, the collimator 312a is not limited to a reflectance type but may be provided as a transmission type by using at least one lens. In this case, the at least one lens may be coated with a material capable of minimizing reflectance.

Referring to FIG. 7B, as described above, the polarizer 314a may transmit and output only an element oscillating in a specific direction, from among incident light. Thus, the polarizer 314a may linearly polarize the incident light. For example, in FIG. 7B, a bi-directional arrow A1 refers to a polarization axis, and the polarizer 314a transmits only an element oscillating in the same direction as the polarization axis, from among the light incident to the polarizer 314a. Here, a horizontal straight line A2 refers to an optical axis, and a rotation angle (i.e., azimuth) of the polarizer 314a with respect to the optical axis has a first angle β.

In the optical inspection apparatus 1000 according to the present embodiment, the polarizer 314a of the illumination optics 310 may include a rotary polarization filter. For example, the rotary polarization filter may rotate the polarizer 314a as illustrated with a curved bi-directional arrow A3 to change an azimuth (i.e., a polarization direction) of the polarizer 314a. When the polarizer 314a includes the rotary polarization filter and the stage 400 is a rotary stage (e.g., an R-θ stage), the rotation of an inspection target may be compensated.

More specifically, when a critical dimension (CD) of line-and-space (L/S) patterns of the inspection target 2000 is typically measured, the polarizer 314a may polarize light and allow the polarized light to be incident to the inspection target 2000 so that a direction in which light oscillates is equal to a direction in which the L/S patterns extend. When the rotary stage 400 (e.g., the R-θ stage) is used, even if a polarization direction of light is equalized to a direction in which patterns of an initial ROI of the inspection target 2000 extend, a polarization direction of light may deviate from a direction in which patterns of another ROI of the inspection target 2000 extend, at a predetermined angle. In this case, the rotary polarization filter may change a polarization direction of light and equalize the polarization direction of the light to a direction in which the L/S patterns of the inspection target 2000 extend. Thus, the rotary polarization filter may improve precision of measurements. Meanwhile, when the stage 400 is an x-y-z stage, the polarizer 314a may include a fixed polarization filter.

FIGS. 8A and 8B are diagrams illustrating the concept of a double telecentric optics to which an imaging optics of an image obtaining apparatus is applied, in an optical inspection apparatus according to an example embodiment of the inventive concept.

Referring to FIGS. 8A and 8B, generally, an angle of refraction of a lens may vary according to a curvature of the lens, and a focal length of the lens may vary according to the angle of refraction of the lens. As an angle of refraction of a lens becomes higher (or as the lens becomes thicker), a focal length of the lens may become shorter and greater wide-angle effects may be expected. Also, due to an aberration phenomenon, a peripheral portion of an image of the lens may blur or a shape of the image of the lens may be distorted. The aberration may typically include a chromatic aberration and a spherical aberration. Here, the chromatic aberration refers to a phenomenon where a lens has different refractive indices for different wavelengths of light and fails to focus all light beams to the same convergence point to cause a blur in image. Also, spherical aberration here refers to a phenomenon where a spherical lens fails to focus light beams incident to a center of the spherical lens and light beams incident to an edge of the spherical lens to the same convergence point to cause a blur in image. In general, the spherical aberration may be obviated by enabling spherical aberrations of lenses to counteract each other during a process of designing the lenses.

Although chromatic aberration is not greatly problematic in capturing an image of one point, when an image of a wide region is captured in a wide wavelength band, chromatic aberration may inevitably occur to degrade precision of measurements.

To remove the chromatic aberration, the imaging optics may be configured as telecentric optics. The telecentric optics may refer to optics in which light is emitted through a lens in the form of light of an infinite light source or collimated light. Conversely, the telecentric optics may refer to optics in which light of an infinite light source or collimated light is incident to a lens and condensed to a focal position of the lens. In this case, the telecentric optics may ignore the perspective of objects and minimize chromatic aberration.

As shown in FIG. 8B, the telecentric optics may be prepared by locating the inspection target 2000 or an image sensor of the CCD camera 330 in a focal position of a lens 312 or 314 and allowing light emitted from the lens 312 or 314 to travel parallel to a central axis (an alternating long-short dashed line). Although FIG. 8B illustrates a simple case in which collimated light is obtained by one lens 312 or 314, a plurality of lenses may be used to obtain collimated light. Also, in the telecentric optics, light incident to the lens 312 or 314 may be vertically incident to a focal position, for example, the inspection target 2000 or the image sensor of the CCD camera 330.

In the optical inspection apparatus 1000 according to the present embodiment, an imaging optics 320a may be configured as a double telecentric optics to remove chromatic aberration and improve precision of measurement. The double telecentric optics may be prepared by locating the inspection target 2000 in a focal position of an objective lens 322 and locating the image sensor of the CCD camera 330 in a focal position of an imaging lens 328. Light may travel in the form of collimated light (i.e., light of an infinite light source) between the objective lens 322 and the imaging lens 328. At least one lens (e.g., a tube lens) may be located between the objective lens 322 and the imaging lens 328. Also, each of the objective lens 322 and the imaging lens 328 may include at least two lenses.

FIG. 9A is a plan view of a 2D image of an ROI of a wafer, which is obtained by an optical inspection apparatus 1000 according to an example embodiment of the inventive concept. FIG. 9B is a graph of reflectance relative to wavelength in each pixel of the 2D image of FIG. 9A. FIG. 9C is a perspective view of a height profile image of the ROI based on the graph of FIG. 9B.

Referring to FIG. 9A, in the optical inspection apparatus 1000 according to the present embodiment, a 2D image of an ROI of the inspection target 2000 (e.g., a wafer) may be generated by the image obtaining apparatus 300. Here, the ROI may correspond to a dashed square of a wafer or an enlarged dashed square. As shown in FIG. 2, a plurality of 2D images may be generated to correspond to a plurality of wavelength regions. Each of the 2D images may include a plurality of pixels. Also, each of the pixels included in each of the 2D images may include information about intensity or reflectance. In the plan view of 2D image, a hatched portion may correspond to an oxide film, such as a silicon oxide (SiO₂) film, and the remaining portion may correspond to a silicon substrate.

Referring to FIG. 9B, in the optical inspection apparatus 1000 according to the present embodiment, the analysis device (refer to 500 in FIG. 1) may receive information of a 2D image of each wavelength region from the image obtaining apparatus 300, analyze the information, and generate a reflectance graph for inspection, which is a graph of reflectance relative to a wavelength region of a pixel, as shown in FIG. 9B. Here, the x-axis may indicate wavelength regions, the y-axis may indicate reflectance, and the z-axis may indicate a pixel number.

More specifically, as can be seen from the 2D images of FIG. 2, an intensity or reflectance of a first pixel pixel 1(x,y) may vary according to a wavelength region. For example, a first pixel pixel 1(x,y) in a first wavelength region λ1 may have a reflectance of about (or exactly) 0.2, and a first pixel pixel 1(x,y) in a third wavelength region λ3 may have a reflectance of about (or exactly) 0.4. Wavelength regions may be divided from one another very minutely, and reflectance of each of the pixels may be indicated in each of the wavelength regions, so that the reflectance graph for inspection shown in FIG. 9B may be obtained.

Referring to FIG. 9C, in the optical inspection apparatus 1000 according to the present embodiment, the analysis device 500 may compare the reflectance graph for inspection of FIG. 9B with a reference reflectance graph stored in a database and obtain information of a state of the ROI of the inspection target 2000 (e.g., the wafer) based on the comparison result. The state of the ROI may be, for example, a thickness, a pattern critical dimension (CD), or a structure of a thin film in the ROI. The structure of the thin film of the ROI may be understood as a three-dimensional (3D) structure as shown in FIG. 9C.

Specifically, a plurality of reference reflectance graphs may be compared with the reflectance graph for inspection of FIG. 9B, and a reference reflectance graph approximate to the reflectance graph for inspection of FIG. 9B may be extracted. Thereafter, information of a thickness, a CD, or a structure of the thin film of the ROI may be obtained based on the extracted reference reflectance graph. In other words, since the reference reflectance graphs are obtained by using material layer structures including thin films of which thicknesses, CDs, or structures correspond to already known information, when the reference reflectance graph approximate to the reflectance graph for inspection is extracted, information of the thin film of the ROI may be directly obtained based on the information of the material layer structure corresponding thereto.

In some cases, it may be determined whether or not a state of the ROI of the inspection target 2000 (e.g., a wafer) is normal, based on the comparison result. For example, based on the comparison result, it may be determined whether the thin film is formed to a normal thickness in the ROI, whether a pattern having a normal CD is formed, or whether the thin film has a normal structure. Specifically, when a thickness, a pattern CD, or a structure of a thin film to be formed in the ROI are specified, a reference reflectance graph of a material layer corresponding to the thickness, pattern CD, or structure of the thin film may be retrieved from a database and compared with a graph of reflectance relative to wavelength region in each of the pixels of the ROI (i.e., a reflectance graph for inspection in the ROI). Thereafter, it may be determined whether the thin film formed in the ROI is normal by determining whether the comparison result is within a permitted limit.

FIG. 10 is a flowchart of an optical inspection method according to an example embodiment of the inventive concept. The flowchart of FIG. 10 will be described with reference to FIG. 1 for brevity.

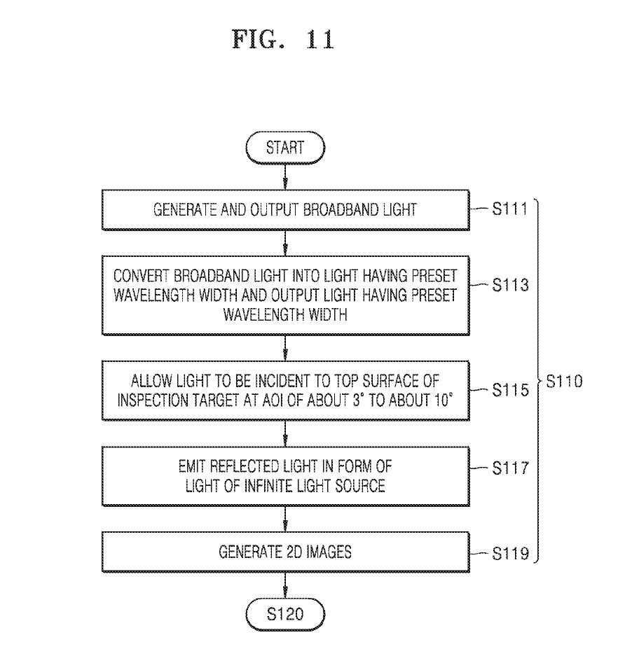

Referring to FIG. 10, 2D images of an inspection target 2000 are generated in a plurality of wavelength regions by using an optical inspection apparatus 1000 (S110). For example, 2D images of the inspection target 2000 (e.g., 2D images of an ROI of a wafer) may be generated in a plurality of wavelength regions by the CCD camera 330 of the image obtaining apparatus 300 of the optical inspection apparatus 1000. Thus, as shown in FIG. 2, a plurality of 2D images of the ROI of the wafer may be generated to correspond to the plurality of wavelength regions. A process of generating the 2D images of the inspection target 2000 will be described in further detail with reference to FIG. 11.

Next, by using the optical inspection apparatus 1000, the inspection target 2000 is inspected by analyzing the 2D images of the inspection target 2000 (S120). By using the analysis device 500 of the optical inspection apparatus 1000, a reflectance graph for inspection may be generated based on the 2D images of the plurality of wavelength regions obtained by the image obtaining apparatus 300. Here, the inspection reflectance graph may be, for example, a graph of reflectances relative to wavelength region in each pixel of the 2D image as shown in FIG. 9B.

Next, after the reflectance graph for inspection is generated, the analysis device 500 may compare the reference reflectance graph stored in the database with the reflectance graph for inspection and obtain information about the inspection target 2000. For example, the information of the inspection target 2000 may be, for example, a thickness of a thin film, a pattern CD of the thin film, or a structure of the thin film in the ROI of the wafer. Furthermore, the information of the inspection target 2000 may be, for example, information regarding whether the thickness of the thin film is within a permitted limit, whether the pattern CD of the thin film is within a permitted limit, or whether the thin film has an appropriate structure in the ROI of the wafer.

The process of obtaining the information of the inspection target 2000 by comparing the reflectance graph for inspection with the reference reflectance graph may be the same as described with reference to FIGS. 9A to 9C.

FIG. 11 is a detailed flowchart of operation S110 of generating a 2D image of an inspection target in the optical inspection method of FIG. 10 according to an example embodiment of the inventive concept. The flowchart of FIG. 11 will be described with reference to FIG. 1. The same descriptions as in FIG. 10 will be simplified or omitted.

Referring to FIG. 11, the light source 100 generates and outputs broadband light (S111). For example, the broadband light generated by the light source 100 may have a wavelength range of about (or exactly) 170 nm to about (or exactly) 2100 nm. The broadband light may be incident to the monochromator 200 through the first optical fiber 150.

Next, the monochromator 200 converts the broadband light into light having a preset wavelength width and outputs the light having the preset wavelength width (S113). Here, the wavelength width may be several nm. Accordingly, the monochromator 200 may convert the broadband light into monochromatic light and output the monochromatic light. In an embodiment, the monochromator 200 does not output only one monochromatic beam but outputs a plurality of monochromatic beams while sweeping at intervals of the wavelength width. In other words, while converting the broadband light into the monochromatic light and outputting the monochromatic light, the monochromator 200 may output a plurality of monochromatic beams to correspond to a plurality of wavelength regions. For instance, while outputting monochromatic light having a wavelength width of about (or exactly) 5 nm, the monochromator 200 may sweep in a wavelength range of about (or exactly) 250 nm to about (or exactly) 800 nm and output a plurality of monochromatic beams continuously or intermittently. Light output by the monochromator 200 may be incident to the image obtaining apparatus 300 through the second optical fiber 250.

By using the illumination optics 310 of the image obtaining apparatus 300, light from the monochromator 200 is incident to the top surface of the inspection target 2000 at an AOI of about (or exactly) 3° to about (or exactly) 10° (S115). Thus, the illumination optics 310 may be configured as inclined optics with respect to the inspection target 2000. For example, the illumination optics 310 may appropriately control an angle of the first mirror 316 and allow light to be incident to the top surface of the inspection target 2000 at an AOI of about (or exactly) 5°.

By using the imaging optics 320 of the image obtaining apparatus 300, light reflected by the inspection target 2000 is emitted in the form of light of an infinite light source or collimated light (S117). For example, the imaging optics 320 may be configured as a double telecentric optics. The double telecentric optics may be the same as described with reference to FIGS. 8A and 8B. Meanwhile, the imaging optics 320 may have an NA of about (or exactly) 0.03 to o (or exactly) 0.08 and a magnification ratio of about (or exactly) 2 to 10 times.

The CCD camera 330 receives light from the imaging optics 320 and generates a 2D image (S119). Since the monochromator 200 generates a plurality of monochromatic beams corresponding to a plurality of wavelength regions and allows the plurality of monochromatic beams to be incident to the image obtaining apparatus 300, the CCD camera 330 may generate a plurality of 2D images in the plurality of wavelength regions to correspond to the plurality of monochromatic beams. Each of the 2D images may include a plurality of pixels, each of which includes information about intensity or reflectance of light. The CCD camera 330 may have high QE of about (or exactly) 30% or higher in a UV band to compensate for light intensity in the UV band. Also, the CCD camera 330 may adopt a dynamic shutter speed technique to remove non-uniformity in light intensity between the wavelength regions.

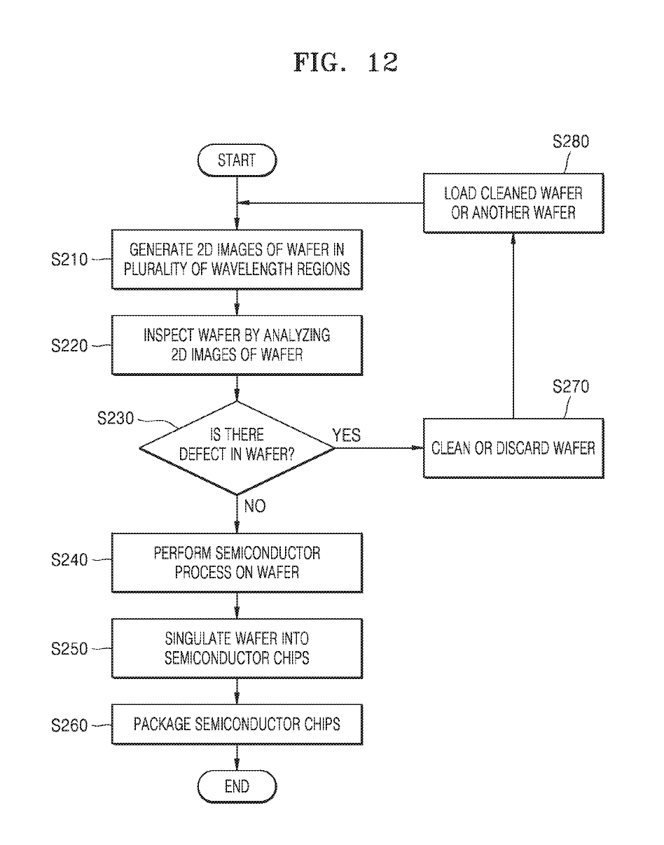

FIG. 12 is a schematic flowchart of a method of fabricating a semiconductor device by using an optical inspection method according to an example embodiment of the inventive concept. The flowchart of FIG. 12 will be described with reference to FIG. 1. The same description as in FIGS. 10 and 11 will be simplified or omitted.

Referring to FIG. 12, operation S210 of generating a 2D image of a wafer and operation S220 of inspecting the wafer may be the same as described with reference to FIGS. 10 and 11. However, in operation S210 of generating the 2D image of the wafer, a 2D image of an ROI of a specific wafer may be generated instead of a 2D image of the inspection target 2000. Also, in operation S220 of inspecting the wafer, the ROI of the specific wafer may be inspected instead of the inspection target 2000. The wafer may include a thin film formed on a substrate. The thin film may have one of various structures and one of various thicknesses and be formed on the substrate by using a semiconductor process.

After operation S220 of inspecting the wafer, it is determined whether there is a defect in the wafer, based on the inspection result (S230). It may be determined if there is a defect in the wafer based on information of a thin film, which is obtained in operation S220 of inspecting the wafer. For example, by determining whether a thickness of the thin film is within a permitted limit, whether a pattern CD of the thin film is within a permitted limit, or whether a structure of the thin film is a required structure, it may be determined whether there is a defect in the wafer. When a thickness, a pattern CD or a structure of a thin film to be formed are previously defined, it may be determined if there is a defect in the wafer by determining whether a difference between a reflectance graph for inspection and a reference reflectance graph is within a permitted limit.

If there is no defect in the wafer (No), a semiconductor process is performed on the wafer (S240). The semiconductor process on the wafer may include various processes. For example, the semiconductor process on the wafer may include a deposition process, an etching process, an ion process, and a cleaning process. By performing the semiconductor process on the wafer, integrated circuits (ICs) and interconnections required for a semiconductor device may be formed. The semiconductor process on the wafer may include a process of testing a wafer-level semiconductor device. Meanwhile, other thin films may be formed during the semiconductor process on the wafer, and operation S210 of generating the 2D image of the wafer and operation S220 of inspecting the wafer may be performed again on each of the thin films.

In addition, when operation S210 of generating the 2D image of the wafer and operation S220 of inspecting the wafer are performed for a simple measurement, the process may directly enter operation S240 of performing the semiconductor process on the wafer without operation S230 of determining whether there is a defect in the wafer.

If semiconductor chips are completely formed in the wafer due to the semiconductor process on the wafer, the wafer is singulated into the respective semiconductor chips (S250). The singulation of the wafer into the semiconductor chips may be performed by using a sawing process, such as a blade or a laser sawing process.

Thereafter, a packaging process is performed on the semiconductor chips (S260). The packaging process may refer to a process of mounting the semiconductor chips on a printed circuit board (PCB) and encapsulating the PCB on which the semiconductor chips are mounted, with an encapsulant. The packaging process may include forming a stack package by stacking a plurality of semiconductor layers on the PCB or forming a Package on Package (PoP) structure by stacking a stack package on a stack package. A semiconductor device or a semiconductor package may be completely formed by performing the packaging process on the semiconductor chips. A test process may be performed on the semiconductor package after the packaging process.

Otherwise, if there is a defect in the wafer (Yes), the wafer is cleaned or discarded (S270). For example, there may be a defect in the wafer for two reasons. First, since a foreign material is present on an ROI of the wafer, measurements may be wrong. Second, since there is an error in a semiconductor process of forming a thin film, the thin film itself may be erroneously formed. In the first case, the wafer may be cleaned to remove the foreign material. However, in the second case, the error cannot be solved due to a cleaning process, so the wafer itself may be discarded.

Thereafter, the cleaned wafer or another wafer may be loaded into the optical inspection apparatus 1000 (S280), and operation S210 of generating a 2D image of the wafer may be performed. Here, another wafer may be a wafer obtained by forming a thin film on a substrate under new semiconductor process conditions. Accordingly, when another wafer is loaded in operation S280 of loading the wafer into the optical inspection apparatus 1000, a process of forming a thin film on a substrate under new semiconductor process conditions may be performed before operation S280.

While the inventive concept has been particularly shown and described with reference to embodiments thereof, it will be understood that various changes in form and details may be made therein without departing from the spirit and scope of the inventive concept.

1. An optical inspection apparatus comprising:
a light source configured to generate and output broadband light;
a monochromator configured to convert the broadband light into a plurality of monochromatic beams of different wavelengths and sequentially output the monochromatic beams, wherein each beam has a preset wavelength width and corresponds to one of a plurality of different wavelength regions;
illumination optics configured to allow each monochromatic beam output from the monochromator to be incident to a top surface of an inspection target at a predetermined angle of incidence (AOI);
imaging optics configured to emit light reflected by the inspection target in a form of light of an infinite light source; and
a detector configured to receive the emitted reflected light from the imaging optics and generate two-dimensional (2D) images of the inspection target from the received emitted reflected light,
wherein the optical inspection apparatus inspects the inspection target by analyzing the 2D images of the plurality of wavelength regions.

2. The apparatus of claim 1, wherein the imaging optics is configured as a double telecentric optics.

3. The apparatus of claim 1, wherein the monochromator comprises a grating device and the monochromator adjusts an angle of the grating device to generate each of the monochromatic beams.

4. The apparatus of claim 3, wherein the preset wavelength width is about 5 nm and the monochromatic beams include monochromatic beams in a wavelength range of about 250 nm to about 800 nm.

5. The apparatus of claim 1, wherein the illumination optics comprises a collimator configured to collimate each monochromatic beam output from the monochromator, a polarizer configured to polarize light output from the collimator, and a mirror configured to reflect light output from the polarizer to be incident to the top surface of the inspection target,
wherein the mirror allows light to be incident to the top surface of the inspection target at an AOI of about 3° to about 10°.

6. The apparatus of claim 5, wherein the inspection target is located on a rotary stage that is configured to move, and
the polarizer is a rotary polarization filter configured to change a polarization direction according to a shape of a pattern in a region of interest (ROI) of the inspection target.

7. The apparatus of claim 5, wherein the collimator is of a reflectance type and coated with a material capable of increasing reflectance of ultraviolet (UV) light.

8. The apparatus of claim 1, wherein the imaging optics has a numerical aperture (NA) of about 0.03 to about 0.08 and a magnification ratio of 2 times to 10 times.

9. The apparatus of claim 8, wherein the imaging optics comprises at least one mirror configured to change a path of light,
wherein lenses included in the imaging optics are coated with a material capable of decreasing reflectance to have a reflectance of less than about 3%.

10. The apparatus of claim 1, wherein the detector is a charge-coupled device (CCD) camera, and the CCD camera has a quantum efficiency (QE) of about 30% or higher in a UV band.

11. The apparatus of claim 1, wherein the detector is a charge-coupled device (CCD) camera, and the CCD camera dynamically controls a shutter speed according to intensity of incident light.

12. The apparatus of claim 1, wherein the illumination optics and the imaging optics do not include a beam splitter.

13. The apparatus of claim 1, further comprising an analysis device,
wherein the analysis device generates a reflectance graph for inspection based on the 2D images of the plurality of wavelength regions, compares the reflectance graph for inspection with a reference reflectance graph, inspects a thickness or a pattern critical dimension (CD) of a thin film of the inspection target, and compensates for a difference in intensity and a QE difference of the detector between different wavelength regions of the broadband light.

14-24. (canceled)

25. A method of fabricating a semiconductor device, the method comprising:
generating two-dimensional (2D) images of a wafer in a plurality of wavelength regions by using a broadband light source, a monochromator, and an image obtaining apparatus;
analyzing, by an analysis device, the 2D images of the wafer in the plurality of wavelength regions to determine whether a defect is present in the wafer; and
performing a semiconductor process on the wafer when a result of the analyzing indicates no defect is present in the wafer,
wherein the image obtaining apparatus allows light output from the monochromator to be incident to a top surface of the wafer without a beam splitter, allows light reflected by the wafer to travel in a form of light of an infinite light source, and generates the 2D images of the wafer.

26. The method of claim 25, wherein the image obtaining apparatus generates the 2D images of the wafer by:
converting light output from the broadband light source into monochromatic light having a preset wavelength width and outputting the monochromatic light using the monochromator;
allowing monochromatic light output from the monochromator to be incident to the top surface of the wafer at an angle of incidence (AOI) of about 3° to about 10° by using illumination optics;
emitting light reflected by the wafer in the form of light of an infinite light source by using imaging optics; and
generating, by a charge-coupled device (CCD) camera, the 2D images using the emitted reflected light,
wherein, during the outputting of the monochromatic light, the monochromator sequentially outputs monochromatic beams of different wavelengths each corresponding one of the plurality of wavelength regions.

27. The method of claim 26, wherein the imaging optics is configured as a double telecentric optics and has a numerical aperture (NA) of about 0.03 to about 0.08 and a magnification ratio of about 2 times to about 10 times, and
the CCD camera has a quantum efficiency (QE) of about 30% or higher in an ultraviolet (UV) band and dynamically controls a shutter speed according to an intensity of incident light.

28. The method of claim 25, wherein the analyzing of the wafer comprises:
generating a reflectance graph for inspection based on the 2D images of the plurality of wavelength regions;
comparing the reflectance graph for inspection with a reference reflectance graph stored in a database; and
obtaining information of a thickness, a pattern critical dimension (CD), or a structure of a thin film in a region of interest (ROI) of the wafer, based on a result of the comparing.

29. The method of claim 25, further comprising cleaning or discarding the wafer when a result of the analyzing indicates the defect is present in the wafer.

30. The method of claim 25, after the performing of the semiconductor process on the wafer, further comprising:
singulating the wafer into respective semiconductor chips; and
packaging the semiconductor chips.

31-33. (canceled)
